(19) United States
(12) Patent Application Publication
(10) Pub. No.: US 2026/0342079 A1
(43) Pub. Date: Oct. 29, 2026

(54) INTEGRATED POINT-OF-LOAD POWER CONTROLLER FOR FUEL CELLS COUPLED WITH AI COMPUTE TRAYS, SERVER RACKS, AND DATA CENTERS

(71) Applicants: Mark TELEFUS, Orinda, CA (US); MobiVolt Defense LLC, Livermore, CA (US)

(72) Inventors: Mark TELEFUS, Orinda, CA (US); Ian KAYE, Livermore, CA (US); Suhail ZAIN, San Ramon, CA (US)

(21) Appl. No.: 19/656,907

(22) Filed: Apr. 23, 2026

Related U.S. Application Data
(60) Provisional application No. 63/794,324, filed on Apr. 24, 2025.

(51) Int. Cl. H02J 1/00; H02J 1/102; H02J 1/16; H02J 101/30; H02J 105/42; H05K 7/14

(52) U.S. Cl. CPC H02J 1/001; H02J 1/102; H02J 1/16; H05K 7/1492; H02J 2101/30; H02J 2105/425

(57) ABSTRACT

A system and method for powering high-density compute hardware are disclosed. One or more hydrogen fuel cell power modules are positioned at or near a compute tray, server rack, board, package, or other point of load and generate direct-current power for one or more processors, accelerators, memory devices, or associated electronics. In various embodiments, the modules deliver low-voltage, high-current power directly or near-directly to compute devices, thereby reducing or eliminating intermediate power conversion stages. The system can include sealed gas couplings, coolant couplings, hot-swappable module structures, hydrogen distribution manifolds, transient support devices, and control circuitry responsive to dynamic compute demand. The disclosed architecture reduces grid dependence, conversion loss, copper-intensive distribution, and infrastructure overhead for artificial intelligence and other high-density computing systems.

### CROSS-REFERENCE TO RELATED APPLICATIONS

The present application claims the benefit of U.S. Provisional Patent Application No. 63/794,324, filed on Apr. 24, 2025, and titled “Hydrogen (H2) to DC Power Converter,” the disclosure of which is incorporated herein by reference in its entirety.

### FIELD OF THE INVENTION

Embodiments of the present invention relate generally to electrical power delivery for high density computing systems and, more particularly, to hydrogen fuel cell based direct current power generation, regulation, and point-of-load delivery for artificial intelligence compute trays, graphics processing unit clusters, server racks, and associated data center infrastructure.

### BACKGROUND OF THE INVENTION

Artificial intelligence training and inference systems are driving a rapid increase in rack power density. Modern accelerated servers can consume hundreds of kilowatts per rack, and projected next generation platforms are expected to continue increasing in power consumption as the number and performance of GPUs, tensor processors, memory devices, and interconnect components rise.

Conventional data center power architectures were not designed for these load profiles. In a traditional grid supplied arrangement, utility power is stepped down, conditioned, converted, stored, and redistributed through multiple alternating current to direct current and direct current to direct current conversion stages before usable low voltage power reaches a processor package. Each conversion stage introduces losses, thermal burden, capital cost, maintenance complexity, and potential failure points.

Even an ostensibly improved facility architecture may still route power through a utility megawatt grid interface, delivering power at high voltage AC such as 35 kVA, a solid state transformer, rectification to DC power or comparable front end conversion stage, a high voltage direct current distribution bus, a rack level direct current power supply, and one or more downstream point of load conversion stages that reduce voltage from approximately plus or minus 800 volts DC to about 50 volts, then to about 12 volts, and ultimately to about 0.8 volts or another processor operating voltage before the power reaches a GPU, CPU, memory device, accelerator, or processor package. This progression means that AI infrastructure is burdened by multiple expensive electrical domains, each of which requires specialized power electronics, protection circuitry, conductors, cooling capacity, controls, and physical installation space.

The conventional approach is therefore costly both in capital expenditure and operating expenditure. Large transformers, switchgear, UPS systems, rectifiers, rack power shelves, busbars, backup batteries, and distributed DC to DC converters must each be purchased, installed, monitored, cooled, and serviced. Every intermediate conversion stage dissipates heat, which in turn increases liquid cooling and HVAC burden, raises power usage effectiveness, and causes the operator to buy additional upstream generation and distribution capacity just to deliver a smaller fraction of useful electrical work to the compute silicon. For AI systems operating at very low voltage and very high current, the cost penalty is amplified because resistive losses, copper mass, connector complexity, and thermal management requirements rise sharply as the current to run the chips increases.

These inefficiencies are especially problematic in AI environments because the useful load may represent only a portion of the power originally drawn from the grid. For example, a single GPU or accelerated compute assembly can require substantially greater, up to 60%, upstream grid input source once power conversion loss, transmission loss, and non-IT facility overhead are taken into account.

Dynamic AI workloads further stress conventional infrastructure. Training, inference, checkpointing, and parallel cluster scheduling can cause rapid swings in rack level demand. Power can change materially within minutes, and in some cases at far faster transient rates, which places stress on utility interconnects, switchgear, uninterruptible power supplies, transformers, busbars, and backup generation assets.

Another limitation of conventional architectures is the use of copper intensive distribution structures for high current loads. As rack demand rises, thicker busbars, larger conductors, and expanded power conversion hardware consume valuable physical space that could otherwise be used for compute devices, networking, thermal management components, or service access. This physical penalty can reduce compute density and complicate retrofits in legacy facilities.

Maintenance and reliability also become more difficult with conventional arrangements. High current distribution hardware may be hazardous to service under load, and failure at a rack level backbone can interrupt operation of multiple expensive compute modules simultaneously. Thermal expansion, electrical resistance changes, and connection degradation can further undermine uptime in mission critical installations.

Utilities are also struggling to keep pace with the scale and speed of AI data center expansion. New hyperscale facilities may require hundreds of megawatts or more, while utility interconnection timelines can extend for years. The result is that available compute deployment is constrained not only by semiconductor supply, but also by the availability of deliverable electrical power.

Hydrogen fuel cells offer a different approach. Fuel cells are direct current sources that can convert hydrogen, reformed natural gas derived hydrogen, biogas derived hydrogen, renewable hydrogen, or stored liquid hydrogen into electrical energy through an electrochemical reaction. Fuel cells can be deployed in modular arrangements and can be positioned closer to the electrical load than remote utility generation.

Even so, conventional fuel cell deployments have not fully addressed the requirements of next generation AI systems. Existing approaches often remain centralized, continue to rely on large scale intermediate conversion stages, or do not provide the very low voltage, very high current output needed by modern compute trays and processor packages.

### SUMMARY OF THE INVENTION

The present invention provides systems and methods for delivering electrical power to AI compute hardware by generating direct current from hydrogen fuel cell structures at or near a compute tray, server rack, board, package, or other point of load, and conducting power management of the fuel cell output to meet the dynamic power profile of the AI compute hardware. In various embodiments, one or more fuel cell units are mechanically and/or electrically integrated with a compute tray, mounted within a server rack, coupled to a rack manifold, or otherwise arranged to provide low voltage, high current power directly into a power manager which then feeds regulated power to one or more processors, accelerators, memory devices, or supporting electronics. This description outlines hydrogen fuel cells, but it is understood that the invention can be used with other fuel cell such as but not limited to; MCFC (molten carbonate fuel cells) SOFC (solid oxide fuel cells) and HT-PEM (high temperature polymer electrolyte fuel cells) fueled by syngas or natural gas, DMFC (direct methanol fuel cells), alkaline fuel cells, DFAFC (direct formic acid fuel cells) etc.

In one embodiment, a fuel cell power module is coupled to a compute tray or server blade and produces output at a voltage substantially aligned with the requirements of the target load, thereby reducing or eliminating multiple intermediate power conversion stages otherwise used between facility power input and chip power input. The power module may comprise one or more individual cells, a non-stacked cell arrangement, a modular array, or another configuration, and one or more fuel cell power managers selected to deliver a target current and voltage profile for a compute tray or a subset of tray components.

In another embodiment, the fuel cell power module is hot swappable and is mechanically latched to the compute tray or rack using sealed gas couplings, coolant couplings, and electrical interfaces that permit replacement or service with reduced downtime. Hydrogen may be supplied from a pipeline, on-site reformer, electrolyzer, storage vessel, liquid hydrogen source, or other local or remote supply arrangement.

In some embodiments, top side cooling, bottom side cooling, or both may be used in combination with direct low voltage current injection.

In another embodiment, the system includes transient energy storage such as one or more supercapacitors, capacitors, batteries, or hybrid storage structures that cooperate with the fuel cell to satisfy dynamic AI load changes. The storage structure can supply short duration bursts, while the fuel cell follows the longer duration or average demand profile. This arrangement supports fast slew rates, voltage stability, and improved response to oscillating or bursty workloads.

In another embodiment, programmable control circuitry governs operation of the fuel cell system. Sensors may monitor hydrogen pressure, temperature, flow, current, voltage, impedance, compute activity, coolant conditions, and other parameters. A controller, power management integrated circuit, programmable switch array, regulator, or software defined control layer can modulate hydrogen flow, cell engagement, output current, output voltage, transient assistance, and fault response in real time.

In another embodiment, the direct current output is delivered through a low resistance vertical power delivery path to a processor package, substrate, board, ball grid array connection region, interposer, or local power distribution network. Such a path can reduce copper consumption, improve compute packaging efficiency, reduce resistive loss, and increase the number of compute trays or processors that can fit within a rack footprint.

In another embodiment, a rack level or data center level architecture uses a distributed collection of point-of-load fuel cell modules to reduce grid draw, reduce dependency on centralized AC distribution, lower conversion loss, improve scalability, and permit integration of renewable electricity, hydrogen production assets, and local backup energy resources. The invention can be applied to edge data centers, enterprise systems, hyperscale facilities, mobile compute systems, defense systems, and other high density digital infrastructure.

### BRIEF DESCRIPTION OF THE DRAWINGS

FIG. 1 illustrates an exploded perspective view of one embodiment of a compute tray assembly in which a fuel cell power module, associated thermal structures, and a compute board or substrate are arranged in vertically separated relation for integration into a tray-level power architecture.

FIG. 2 illustrates a rack-level embodiment in which a server rack is configured to receive one or more compute trays, and further illustrates tray-mounted power-module embodiments that can be inserted into or removed from the rack.

FIG. 3 illustrates one embodiment of a fuel cell power module mechanically and electrically coupled to a compute tray to provide direct point-of-load or near point-of-load power to one or more GPU, CPU, TPU, memory, or other high-density compute devices.

FIG. 4 illustrates a simplified electrochemical operating diagram of a hydrogen fuel cell showing hydrogen input, oxygen input, ion transport through an electrolyte, electron flow through an external circuit, and water generation.

FIG. 5 illustrates an example hybrid power arrangement in which a hydrogen fuel cell source cooperates with a supercapacitor or other transient support structure to supply dynamic AI compute loads.

FIG. 6 illustrates an example low-profile direct-power fuel cell package adapted for installation within server-compatible hardware and arranged to provide coordinated electrical and thermal integration with compute components.

FIG. 7 illustrates an example copper busbar or high-current rack distribution arrangement and associated structural constraints that motivate direct point-of-load power delivery closer to compute hardware.

### DETAILED DESCRIPTION

Reference will now be made in detail to several embodiments of the invention, examples of which are illustrated conceptually in the accompanying figures. While the invention will be described in conjunction with these embodiments, it will be understood that the description is not intended to limit the invention to those embodiments. On the contrary, the invention is intended to cover alternatives, modifications, and equivalents that fall within the spirit and scope of the appended claims.

For purposes of explanation, the term compute tray may refer to a sled, blade, drawer, board assembly, module carrier, cartridge, tray, or other structure supporting one or more processors, graphics processors, tensor processors, memory devices, network interfaces, or supporting electronics. The term point of load may refer to a location at or near a compute tray, rack, board, package, substrate, interposer, or processor power input where electrical energy is generated, conditioned, or injected for use by the load.

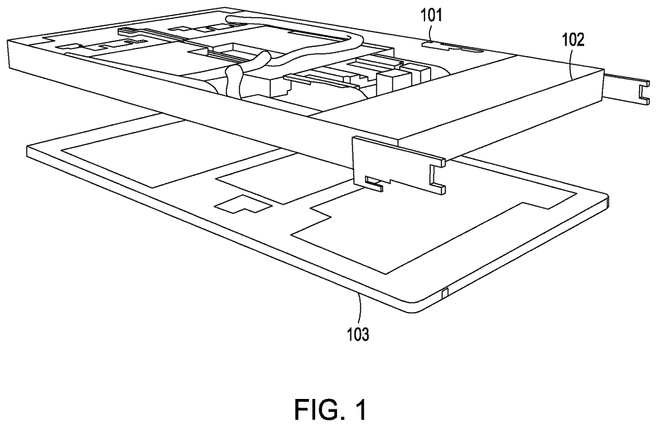

FIG. 1 illustrates an exploded perspective embodiment of a compute tray assembly in which a compute board 101, one or more processor-supporting structures 102, and an overlying tray-compatible fuel cell power module 103 are arranged in vertically separated relation. The exploded view shows how electrochemical generation hardware can be positioned physically close to the compute substrate while still being serviceable as a distinct module or cartridge. In various embodiments, one structure can include a fuel cell housing, coolant-routing features, current-spreading elements, controller circuitry, or combinations thereof, while a separate structure can include a board, package region, accelerator region, memory region, or associated power interface structures.

FIG. 1 is useful because it visually introduces the physical integration concept at the center of the invention: namely, that hydrogen-derived direct-current generation can be placed at or near the compute tray instead of being relegated to remote facility infrastructure. The exploded relationship among the tray-side elements also supports embodiments in which the fuel cell power module is removably mounted, thermally coupled, electrically coupled, or latched into place relative to the compute hardware. The figure therefore corresponds to tray-level and module-level embodiments described herein, including hot-swappable and serviceable cartridge arrangements.

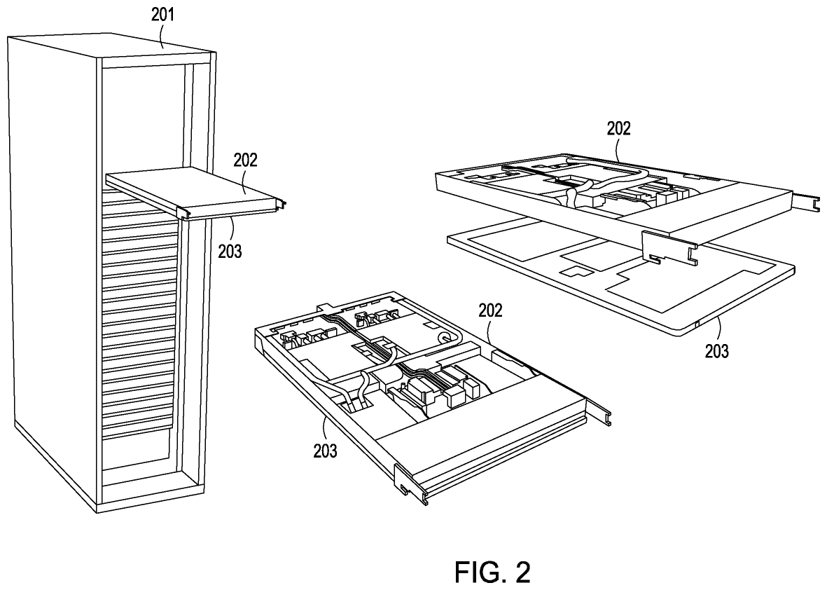

FIG. 2 illustrates a rack-level embodiment in which a server rack 201 receives one or more compute trays 202 and associated fuel cell power modules 203. The illustrated rack and tray views show how tray-level fuel cell power modules can be deployed across multiple rack positions and serviced through insertion and removal of tray-mounted assemblies. In certain embodiments, the rack includes hydrogen distribution structures, coolant distribution structures, electrical backplane interfaces, control wiring, or combinations thereof arranged to support a plurality of compute trays within a common enclosure.

FIG. 2 shows how the invention can be extended from a single compute tray to a rack-deployable system architecture. The figure supports embodiments in which multiple tray-integrated or tray-adjacent fuel cell modules are supplied from a common rack-level manifold or comparable distribution structure. The figure also supports embodiments in which a rack receives different types of trays, different output voltages, or different service procedures, while retaining the advantage of placing power generation substantially closer to the load than in conventional centralized architectures.

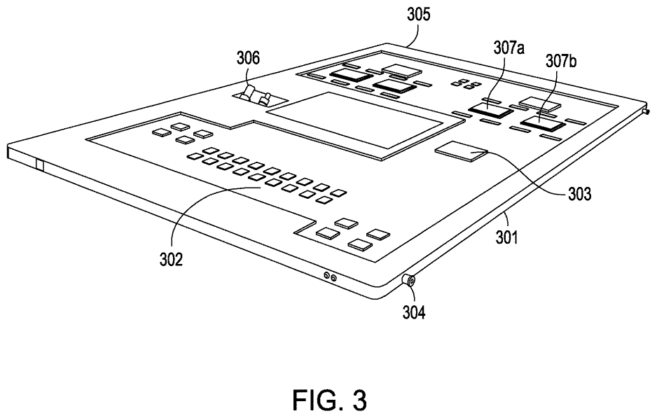

FIG. 3 illustrates one embodiment of a fuel cell power module mechanically and electrically coupled to a compute tray to provide direct point-of-load or near point-of-load power to one or more GPU, CPU, TPU, memory, or other high-density compute devices. In the illustrated embodiment, the fuel cell power module is coupled to a lower side of the compute tray and is arranged to generate low-voltage, high-current direct current power locally at the tray rather than receiving all tray power from an upstream rack-level or facility-level electrical conversion chain. As shown, the module can be configured as a plug-and-play, hot-swappable unit and may comprise an array of individual fuel cell cells or a low-cell-count arrangement rather than a tall conventional stack, thereby preserving a low-profile form factor better suited for installation within a data-center rack service envelope.

In the embodiment of FIG. 3, the illustrated fuel cell power module includes a fuel cell section 301, a power interface printed circuit board 302, a high-speed slew-rate controller 303, one or more 4-point connection structures 304 for latching the fuel cell module to the compute tray, one or more gas connections 305, one or more EDGE coolant inlet and EDGE coolant exit connections 306, and one or more GPU/CPU power output connections positive terminal 307a and negative terminal 307b. The figure further indicates that certain upstream rack-level power paths, such as an incoming 800 VDC rail and one or more conventional intermediate conversion stages, can be reduced or eliminated from the tray architecture because electrical power is instead generated locally by the fuel cell module.

The fuel cell of FIG. 3 can comprise one or more proton exchange membrane fuel cell elements or other hydrogen-compatible electrochemical generation elements configured to convert hydrogen and oxidant into direct current electricity, water, and heat. In preferred embodiments, the fuel cell is arranged as a planar array or otherwise distributed structure to reduce height, increase serviceability, and permit broad current collection. The fuel cell may be sized and configured to deliver output directly usable by compute electronics, such as output in a low-voltage range of about 0.6 volts to about 2.5 volts, and more particularly around 0.7 volts to about 1.2 volts in certain AI embodiments, at very high current, including current on the order of 3000 amperes as indicated in the figure. The power interface PCB 302 shown in FIG. 3 functions as an electrical and control interconnection structure between the fuel cell and the compute tray. In various embodiments, the power interface PCB 302 may include one or more current-spreading planes, laminated copper structures, bus conductors, sense traces, sequencing circuitry, low-power housekeeping supply circuitry, communications interfaces, and optional regulation or impedance-matching structures so that very high current can be delivered with reduced resistive loss and reduced voltage droop.

The high-speed slew-rate controller 303 shown in FIG. 3 can comprise one or more controllers, ASICs, microcontrollers, programmable logic devices, analog control circuits, or combinations thereof configured to regulate the fuel cell power module in response to rapidly varying compute demand. In preferred embodiments, the controller monitors one or more operating parameters including output current, output voltage, hydrogen pressure, hydrogen flow, cell temperature, coolant temperature, coolant flow, compute utilization, or transient support state, and commands one or more valves, regulators, switching networks, transient storage devices, or routing structures so that the tray remains stable during abrupt load changes associated with AI training, inference, checkpointing, or other accelerated workloads. The 4-point connection 304 shown in FIG. 3 can comprise a mechanical and optionally electrical docking structure by which the fuel cell module is removably attached to the compute tray. In one embodiment, four spaced latching points are used to draw the module into a repeatable seated position relative to the tray and maintain alignment between the fuel cell module, the power interface PCB, tray-side power structure, and one or more fluid interfaces during operation and service.

The gas connections 305 shown in FIG. 3 provide fuel delivery to the fuel cell power module and are preferably configured for zero-leak or low-leak hot-swappable service. In one embodiment, the gas connections 305 comprise self-sealing or dry-break couplings that automatically close upon disengagement and may include primary and secondary seals, spring-biased shutoff features, pressure regulators, purge lines, vent lines, leak-detection cavities, or manifold structures so that hydrogen can be introduced, isolated, vented, or monitored safely during operation and service. The EDGE coolant inlet connection 306 to GPU coolant outlet shown in FIG. 3 indicates that, in one embodiment, coolant that has exited a GPU, CPU, accelerator, or related compute cold plate is routed into or toward the fuel cell power module for beneficial thermal conditioning of the module, while the EDGE coolant exit connection to compute tray exit returns coolant away from the fuel cell module toward a tray-side, rack-side, or facility-side cooling path. The GPU/CPU power outputs 307a and 307b represent one or more low-voltage, high-current delivery paths from the fuel cell module toward one or more compute devices on the tray, including example output of approximately 0.7 V at 3000 A. In operation, hydrogen is delivered through the gas connections to the fuel cell power module, the fuel cell electrochemically generates direct current electricity, the power interface PCB and controller cooperate to condition, route, monitor, and safely sequence delivery of that electricity to the compute tray, and the GPU/CPU power outputs provide low-voltage, high-current power directly or near directly to one or more processors or accelerators while the 4-point connection holds the module in place and permits serviceable replacement. Fuel cell coolant connections may also be connected directly to the main rack coolant loop so as to be independent of the compute cooling loop. The total amount of fittings will include fuel inlet and exit, air (or other oxidant) inlet and exit, coolant inlet and exit as well as and purge or overpressure relief lines. Any or all of these fuel cell related fittings are referred to as fluidic connections. The fluidic connections are preferably normally closed on each end, non-latching to allow movement of the compute tray and/or fuel cell without having to reach to the back of the rack, and equipped with zero drip, and minimal dead volume to minimize leakage during changeout.

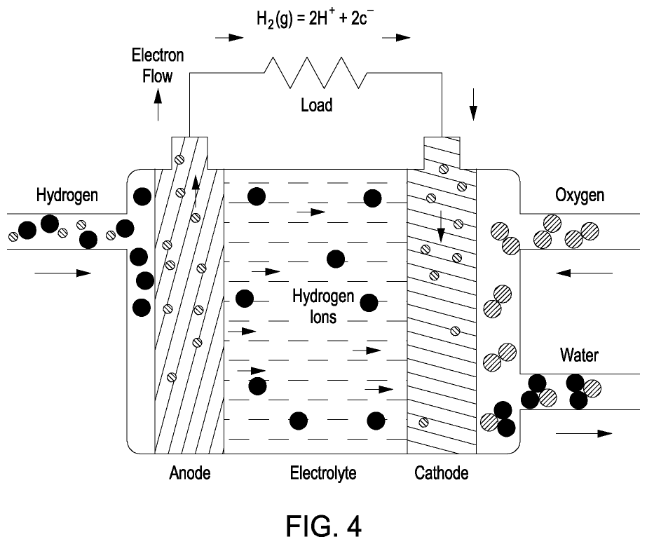

FIG. 4 illustrates an electrochemical operating diagram of a hydrogen fuel cell as can be used in the present invention. As shown, hydrogen is introduced at an anode side, oxygen is introduced at a cathode side, protons or hydrogen ions pass through an electrolyte or membrane, and electrons flow through an external circuit to deliver useful electrical power to a load. Water is produced as a reaction product. This figure provides support for the electrochemical generation principles underlying the tray-level, module-level, and rack-level embodiments described herein.

In embodiments corresponding to FIG. 4, the fuel cell may be a proton exchange membrane fuel cell or another hydrogen-compatible fuel cell architecture suitable for generating direct current. The figure helps explain that the power source is inherently a direct-current source and therefore can be configured for low-voltage, high-current output without requiring the full conventional chain of centralized AC distribution and repeated downstream AC-to-DC and DC-to-DC conversion stages. The figure also supports embodiments using hydrogen flow control, oxidant control, purge handling, water management, and electrochemical load matching as described elsewhere in this specification.

FIG. 4 is logically described as electrochemical context for the disclosed system-level embodiments because it explains the physical basis by which hydrogen is converted into useful electric power. The fuel cell operating principle shown in FIG. 4 underlies the direct-power compute-tray embodiments, rack-distributed embodiments, hybrid transient-support embodiments, and package-proximate delivery embodiments described herein.

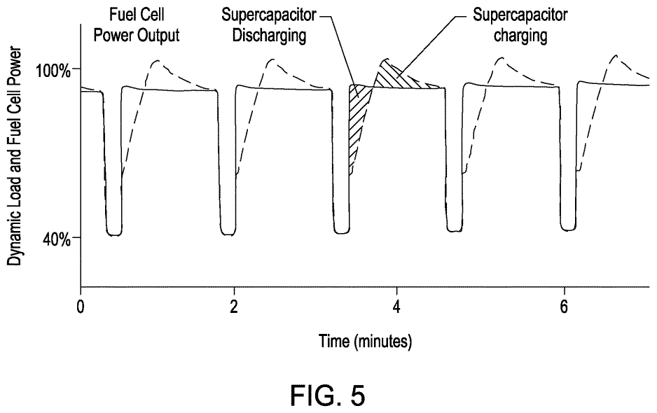

FIG. 5 illustrates one embodiment of a hybrid power arrangement in which a fuel cell source is combined with a supercapacitor or other fast transient support element to support dynamic AI loads. The figure shows repeating intervals in which the fuel cell output follows average demand while the supercapacitor charges and discharges to absorb or deliver short-duration power bursts. The illustrated time-varying curves identify fuel cell output, supercapacitor charging intervals, supercapacitor discharge intervals, and a dynamic AI load profile.

In the embodiment of FIG. 5, the supercapacitor functions as a short-duration, high-cycle-life shock absorber that can respond in milliseconds, while the fuel cell provides sustained energy over longer durations. This arrangement reduces voltage droop at the point of load, avoids the need to oversize the fuel cell for rare peaks, and allows the fuel cell to operate in a more efficient regime while still accommodating the burst-like demand behavior shown in the illustrated load profile. In other embodiments, batteries, hybrid capacitors, or combinations thereof may be used in place of or in addition to the illustrated supercapacitor structure.

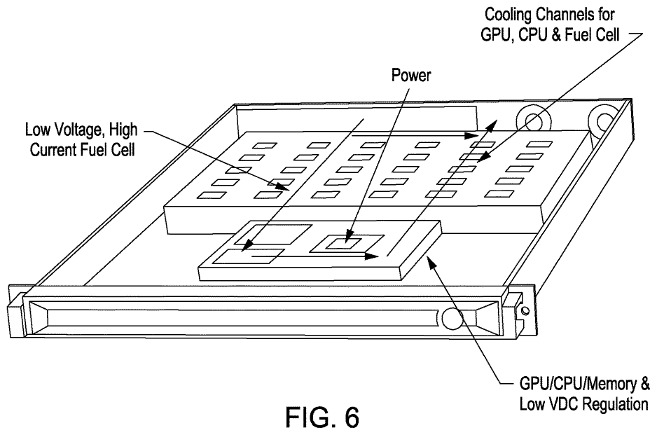

FIG. 6 illustrates one embodiment of a direct-power low-profile fuel cell package adapted for use within server-compatible hardware. The figure shows a low-profile housing containing a fuel cell structure, one or more hydrogen and air or oxidant paths, thermal-management features, and a direct-current output path positioned relative to a compute device. In the illustrated embodiment, the package is arranged so that hydrogen-derived power can be generated close to the compute load while also leveraging coordinated thermal structures within the server environment.

In the embodiment of FIG. 6, the low-profile package can be dimensioned to fit within a 1U envelope, 2U envelope, or sub-envelope mounted above, below, beside, or integral with a compute tray or board. The cooling channels or other thermal structures shown in the package can share coolant paths with one or more compute devices, use separate cooling loops, or perform heat exchange through a shared thermal interface. The illustrated direct-power package therefore demonstrates one way in which the fuel cell form factor can be adapted for practical installation inside a data center while conserving compute volume and reducing infrastructure overhead.

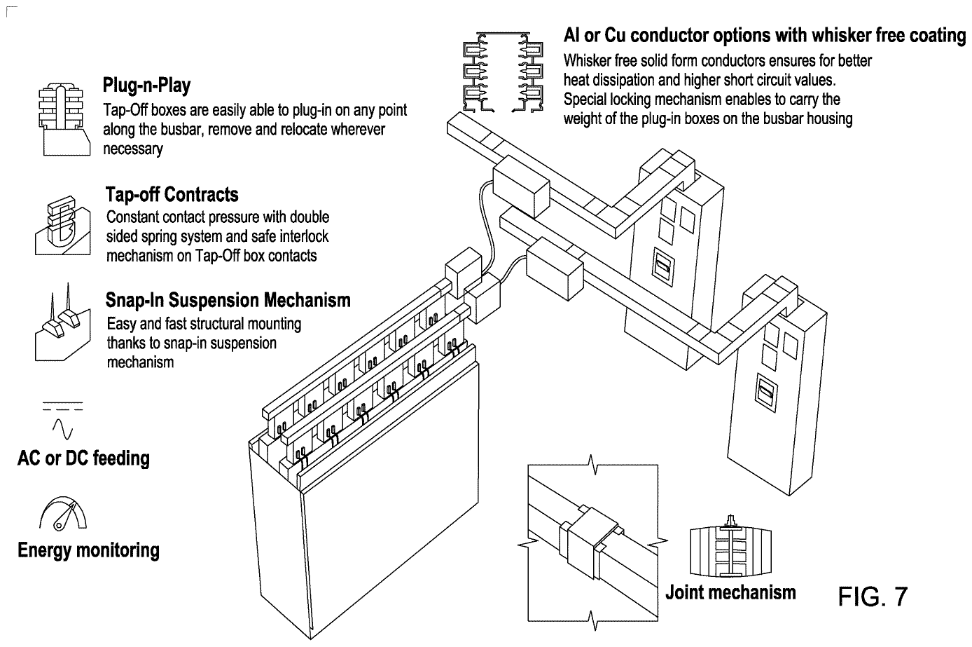

FIG. 7 illustrates an example high-current copper busbar or comparable rack distribution arrangement and associated structural constraints. The illustrated busbars, supports, and rack hardware show how conventional high-current distribution can require bulky conductive members, mechanical supports, clearance regions, and dedicated routing volume within a rack. Such structures can consume space that would otherwise be available for compute hardware, cooling hardware, service access, or other useful rack components.

FIG. 7 illustrates one of the physical limitations addressed by the disclosed architecture. As AI and accelerated computing loads demand higher current at lower voltages, conventional busbar-based distribution becomes increasingly space intensive, copper intensive, thermally challenging, and difficult to service. The distributed point-of-load fuel cell arrangements disclosed herein reduce dependence on such bulky rack-level current-distribution hardware by generating usable direct current substantially closer to the compute load.

In one embodiment, a control architecture includes a sensing subsystem, a hydrogen regulation subsystem, a power switching or programmable array subsystem, a transient storage management subsystem, and one or more compute-interface controllers. These structures can coordinate fuel flow, cell selection, transient response, startup and shutdown, fault handling, thermal management, and point-of-load regulation without requiring a separate centralized facility-scale controller for each load event.

The hydrogen regulation subsystem can include one or more valves, pumps, regulators, compressors, ejectors, reformer interfaces, or other flow control components. The power switching or programmable array subsystem can selectively engage fuel cell elements, alter effective output configuration, connect transient support structures, or isolate a faulty submodule while maintaining operation of the remaining compute hardware.

In another embodiment, the control system determines an effective impedance or operating characteristic of the load and dynamically matches the power source to the load. This can include switching between different groups of cells, changing output routing, altering regulation behavior, or modifying thermal conditions so that power delivery remains stable despite substantial changes in utilization.

In another embodiment, the system is configured to support plug and play servicing. A replacement fuel cell power module can be inserted into a tray or rack position, automatically identified, pressure checked, electrically tested, thermally coupled, and brought online under controller supervision. Faulty modules can be isolated without requiring shutdown of the entire rack or data hall.

The invention is not limited to GPUs or AI accelerators. The disclosed architectures can be used with CPUs, memory expansion devices, networking silicon, custom AI super integrated circuits, tensor processors, field programmable gate arrays, storage accelerators, edge inference modules, defense computing systems, mobile command systems, telecom systems, and other electronic loads benefiting from local direct current generation and high current point-of-load delivery.

Likewise, the hydrogen supply is not limited to a single source or chemistry. Hydrogen can be provided from compressed storage, liquid storage, chemical carriers, electrochemical generation, on-site reforming, remote generation with local transport, or mixed source arrangements. The fuel cell chemistry can include proton exchange membrane fuel cells or other hydrogen compatible fuel cell technologies where suitable.

While certain numeric values and examples have been provided for illustration, such values are not limiting. Output voltages, currents, module sizes, rack sizes, cooling structures, control techniques, and hydrogen handling arrangements can vary depending on implementation. Features described in connection with one embodiment may be combined with features of another embodiment unless the context clearly indicates otherwise.

In preferred embodiments, the disclosed subject matter is directed to more than merely using a fuel cell as a remote or facility-level energy source for a data center. Rather, the disclosed architecture concerns a point-of-load or near-point-of-load hydrogen-fueled power system in which one or more fuel cell modules are physically integrated into the compute power path at the tray level, rack level, board level, interposer level, package level, or combinations thereof. By moving electrochemical generation closer to AI compute hardware, the system can reduce or eliminate multiple conventional conversion stages, reduce copper-intensive distribution structures, reduce thermal loss associated with long electrical paths, and improve uptime through modular replacement and local control.

In one preferred embodiment, a fuel cell power module is configured as a tray-compatible cartridge sized to fit within a standard server service envelope. By way of example and not limitation, the module may fit within a 1U or 2U height class, or may occupy a fractional service envelope mounted below, above, beside, behind, or otherwise adjacent to a compute tray. Example dimensions include a length of about 350 mm to about 600 mm, a height of about 50 mm to about 90 mm, and a depth of about 60 mm to about 180 mm, although other dimensions may be used according to rack standard, current demand, fuel cell chemistry, coolant routing, and desired service access.

In certain embodiments, the module includes a rigid enclosure having a base plate, top cover, sidewalls, internal compression members, seal grooves, mounting ears, latch receivers, and blind-mate connector structures. The enclosure may be formed from sheet metal, machined metal, molded composite, polymer-metal hybrid materials, or combinations thereof. In one embodiment, the enclosure defines separate internal regions for electrochemical elements, gas distribution, coolant distribution, electrical output routing, purge handling, and controller electronics so that serviceability and safety are improved within the confined environment of a data center rack.

In some embodiments, the electrochemical source is not a tall conventional stack, but rather a single cell, a planar array of individual cells, or a low-cell-count stack selected to preserve a low-profile form factor. A planar array can be advantageous where reduced height and broad current spreading are desired. A low-cell-count stack can be advantageous where somewhat higher voltage is desired before impedance matching or local regulation. In still other embodiments, a plurality of fuel cell sections are distributed across different portions of a compute tray or board and are electrically combined by a programmable switching structure.

The module may be field replaceable and hot swappable. In one embodiment, the module rides on rails or guide surfaces and docks through a blind-mate interface into electrical, gas, coolant, and control connectors. In one embodiment, a four-point latching mechanism draws the module into compression against mating seals and contacts. Insertion can occur from a front side, rear side, side wall, top access opening, or bottom access opening of the rack or tray, with front and rear insertion being preferred for aisle-based service. Guide pins, tapered lead-in faces, alignment bosses, capture slots, and over-center latches may be used to ensure repeatable seating and seal compression.

In preferred AI embodiments, the module produces low-voltage, high-current direct current output suitable for direct or near-direct delivery to compute hardware. Example output voltage ranges include about 0.6 volts to about 2.5 volts, and more particularly about 0.7 volts to about 1.2 volts where processor-package or board-level delivery is desired. Output current may range from about 500 amperes to about 5000 amperes, including about 3000 amperes in certain high-density AI tray embodiments. In other embodiments, the module may output an intermediate direct-current voltage, such as about 12 volts, about 24 volts, about 48 volts, or about 50 volts, to support a shortened downstream conversion path.

Depending on implementation, the disclosed architecture can reduce or eliminate one or more conventional conversion stages. In some embodiments, facility-level AC-to-DC conversion remains while tray-level power supply conversion is eliminated. In some embodiments, an 800 VDC rail into the compute tray is eliminated. In some embodiments, 48 VDC and 12 VDC intermediate rails are eliminated. In some embodiments, only a trim regulator, impedance-matching stage, transient-shaping stage, or safety disconnect remains between the fuel cell output and the compute load. In more aggressive embodiments, the fuel cell output is injected into a board-level power plane, bus plate, interposer, package substrate, or vertical power-delivery structure.

Hydrogen may be supplied from any suitable source, including compressed gaseous hydrogen, liquid hydrogen, electrolysis-derived hydrogen, steam-methane-reforming-derived hydrogen, renewable-natural-gas-derived hydrogen, biomass-derived hydrogen, ammonia cracking, methanol reforming, or pipeline-supplied hydrogen. In certain embodiments, hydrogen is generated on-site or near-site and delivered to one or more racks. In certain embodiments, hydrogen is delivered from a centralized plant to a row manifold, rack manifold, tray manifold, or module inlet. In certain embodiments, the system operates in combination with local storage such as liquid hydrogen backup or compressed storage vessels.

In one preferred rack embodiment, hydrogen is distributed through a manifold architecture that includes a primary supply line extending vertically or laterally through the rack and a plurality of branch lines corresponding to respective tray positions. Each branch may include a shutoff valve, pressure regulator, flow restrictor, check valve, purge port, vent port, sensor port, or combinations thereof. In one example, a vertical manifold spine runs along a rack side wall and branch connectors project inward toward individual trays. In another example, a top-fed or bottom-fed dual-rail manifold includes parallel supply lines to reduce pressure drop and permit redundancy. In another example, purge and vent channels run parallel to supply channels within a common manifold body.

The manifold channels may have circular, oval, slot-shaped, rectangular, flattened, or custom cross-sections selected according to flow rate, pressure drop, packaging density, and manufacturability. In some embodiments, independent tray isolation permits removal or service of one tray without shutting down hydrogen flow to neighboring trays. In some embodiments, the manifold supports multiple fuel zones within a rack, such as a first zone serving upper trays and a second zone serving lower trays. In some embodiments, separate purge or recirculation conduits are provided to support startup, shutdown, moisture control, or fuel reuse.

Gas interfaces may be implemented with dry-break or self-sealing couplings. In one embodiment, each gas connector includes a primary face seal and a secondary radial seal so that leakage is inhibited even if one seal is compromised. In one embodiment, spring-biased shutoff members close automatically when the module is undocked. In one embodiment, the gas connector resides within a secondary leak-capture cavity or plenum, which is monitored by a leak sensor. Connector materials may include elastomers, fluoropolymers, metals, ceramics, or composite seal structures selected for hydrogen compatibility, temperature stability, and repeated cycling.

Coolant interfaces may also be blind-mate and self-sealing. In some embodiments, coolant couplings are positioned adjacent to gas couplings within a unified service interface block. In other embodiments, gas and coolant couplings are spatially separated for safety or maintenance reasons. The coolant couplings may include shutoff valves, anti-drip features, quick-disconnect geometry, or keyed arrangements to prevent improper connection. In preferred embodiments, electrical contacts are touch-protected and sequenced so that ground or reference contacts engage before full current contacts, and so that low-power control communication is established before main output conduction is enabled.

In certain embodiments, the fuel cell is thermally integrated with the compute hardware. In one embodiment, warm coolant exiting one or more GPU or CPU cold plates is routed through or adjacent to a thermal region associated with the fuel cell. This can enable beneficial temperature conditioning of the fuel cell without requiring a wholly separate thermal system. In other embodiments, the fuel cell has a separate liquid loop, air loop, refrigerant loop, or phase-change structure. In some embodiments, top-side cooling and bottom-side cooling are both used. In some embodiments, a shared coolant manifold serves both compute loads and the fuel cell module, with branch valves or controllable restrictions used to manage relative flow.

AI workloads are often highly dynamic. Accordingly, preferred embodiments include local transient support in the form of one or more supercapacitors, batteries, flywheels, hybrid capacitors, or equivalent devices. In one preferred embodiment, a supercapacitor is positioned at the tray, module, board, or package level and responds to demand spikes in the millisecond-to-second range while the fuel cell follows a filtered or averaged load profile. This reduces voltage droop and allows the fuel cell to be sized closer to sustained demand rather than rare peak demand. In other embodiments, transient support is shared among multiple modules within a tray or rack.

The disclosed system can additionally use predictive control. In some embodiments, a controller receives workload telemetry, GPU scheduling information, accelerator utilization information, rack power forecasts, or orchestration signals from a data center control layer and adjusts hydrogen flow, oxidant flow, switching state, capacitor charge state, or output configuration in anticipation of an expected power transition. Thus, the system may operate reactively, predictively, or in a hybrid manner.

A control subsystem may include one or more microcontrollers, processors, programmable logic devices, analog front-end circuits, ASICs, gate drivers, valve drivers, sensor interfaces, or communications interfaces. Example sensors include hydrogen pressure sensors, hydrogen flow sensors, hydrogen leak detectors, coolant flow sensors, coolant temperature sensors, output current sensors, output voltage sensors, exhaust temperature sensors, humidity sensors, module presence sensors, latch position sensors, tray presence sensors, and compute activity indicators. The control subsystem may manage startup, purge, valve timing, current ramp rate, transient support dispatch, thermal balancing, fault isolation, module sequencing, and safe shutdown.

In some embodiments, the control subsystem includes a programmable switch array, multiplexer, or reconfigurable current-routing structure that selectively couples different fuel cell sections, transient support elements, or load branches. Such a structure can alter effective output characteristics, improve efficiency across changing load conditions, isolate a faulty cell group, or redistribute current according to demand. In some embodiments, an impedance-matching regulator or programmable power regulator is used to shape the effective source behavior seen by the compute hardware. In certain embodiments, the fuel cell power module includes a direct-current to direct-current converter positioned between the electrochemical power-generation elements and the compute load, the direct-current to direct-current converter being configured to impedance match the source characteristics of the fuel cell power module to the electrical requirements of the compute load. In some embodiments, the module further includes a switching network that selectively reconfigures the electrical relationship of individual cells or groups of cells, including placing at least a portion of the cells in a series electrical relationship, so that the module can present a higher effective voltage during transient conditions, startup conditions, shutdown conditions, insertion conditions, removal conditions, and hot-swap conditions. By combining selective cell reconfiguration with the direct-current to direct-current converter, the system can maintain a desired output voltage, reduce droop during rapid load changes, improve compatibility with changing load impedance, and preserve stable power delivery while a module is being inserted, removed, replaced, or temporarily isolated. In some embodiments, the switching network places a first subset of cells in series during a transient event and returns the first subset to another configuration after the transient event subsides. In some embodiments, the same reconfiguration technique is used during hot-swap operation so that the compute load continues to receive acceptable voltage and current while another source, buffer device, replacement module, or remaining cell subset assumes part of the load

A preferred service procedure for hot swapping a fuel cell module may include any suitable subset of the following operations. First, the system determines that replacement is requested or required. Next, transient support and adjacent power resources are prepared to absorb the load transition. The, main output conduction is reduced or isolated. One or more hydrogen valves are closed and local fuel volume is purged, vented, or depressurized. Self-sealing gas and coolant disconnects are closed. Next, latch mechanisms are released and the module is withdrawn. A replacement module is then inserted through the mechanical guide structure and latched into place. Control communication is established and seal integrity is verified. Coolant and fuel flow are restored. Finally, the module is preconditioned, leak checked, and ramped into load sharing. Some or all of these operations may occur automatically, semi-automatically, or under technician supervision.

Product water generated by the fuel cell may be handled in numerous ways. In some embodiments, water is drained from the module. In some embodiments, water is collected at the rack level. In some embodiments, water is evaporated, condensed, recirculated, used for humidification control, used as feed for electrolysis support equipment, or routed to facility disposal. The system may include water separators, condensers, traps, drains, valves, filters, humidity control elements, or sensors for monitoring water state and location. Exhaust may be routed through a controlled vent path, conditioned exhaust channel, or facility exhaust interface.

Safety features may include hydrogen leak detection, vent path monitoring, airflow verification, sealed interface compartments, flame-arresting structures, ignition suppression spacing, emergency shutoff valves, electrical isolation structures, docking interlocks, and controller-enforced startup and output lockout logic. In one embodiment, fuel flow is inhibited unless the module is fully docked and authenticated. In one embodiment, electrical output is inhibited until gas integrity, coolant integrity, and communication integrity checks are passed. In one embodiment, a rack-level emergency isolation command closes a manifold valve and isolates all trays while maintaining transient support to permit orderly compute shutdown.

Additional embodiments include dual-cartridge arrangements in which a first cartridge contains a fuel cell source and a second cartridge contains transient support, control electronics, purge handling hardware, or combinations thereof. In another embodiment, a rack drawer or shelf receives multiple fuel cell modules through a common hydrogen backplane. In another embodiment, a sealed cassette arrangement encloses the module and its docking interfaces within a secondary containment shell suited for indoor hydrogen deployment.

Additional embodiments include dual-fuel or multi-fuel arrangements in which hydrogen is supplied under normal operation and a secondary fuel source, reformate source, or upstream conversion source is available during startup, extended runtime, or degraded-hydrogen conditions. In some embodiments, oxidant may be ambient air, conditioned air, oxygen-enriched air, or another controlled oxidant source. In some embodiments, a startup heater, humidifier, purge heater, condenser bypass, or catalytic cleanup stage is provided to improve low-temperature or transient operation.

In some embodiments, the module, tray, rack, or controller includes authentication and digital identity features so that only approved modules can dock, energize, or exchange fuel with the system. Authentication may occur through wired handshakes, keyed hardware, machine-readable tags, cryptographic exchanges, or combinations thereof. In some embodiments, a digital twin or service analytics layer tracks module age, usage cycles, seal life, power quality history, predicted degradation, and scheduled maintenance intervals.

In other embodiments, the architecture is extended to board-level, interposer-level, package-level, or chip-adjacent power delivery structures. In a package-interposer embodiment, low-voltage current is injected into an interposer or substrate directly beneath an AI processor package. In a vertical-delivery embodiment, current is delivered through a short and low-resistance path toward a ball-grid array region, package land grid, or similar package-adjacent interface. In some embodiments, a multi-zone rack provides different output voltages or different fuel-cell groupings to different trays, accelerator classes, or compute domains within the same rack.

In still further embodiments, the disclosed system is deployed in a containerized, mobile, military, telecom, edge-compute, or field-deployable data center. Such embodiments may include integrated hydrogen storage, onsite hydrogen generation, hardened service enclosures, shock isolation, environmental sealing, and autonomous startup and shutdown control. In some embodiments, product water is recovered for humidification, cooling support, or another facility use. In some embodiments, additive-manufactured manifold plates, integrated leak-detection channels, advanced ceramics, graphite structures, diffusion layers, catalyst variations, or alternative thermal spreaders are used to further improve packaging density and performance.

In certain embodiments, hydrogen is routed through a building-scale artificial intelligence data center using a hierarchical distribution architecture extending from a central hydrogen plant area to one or more data halls or just outside on the premise, then to one or more rows within each hall, then to one or more racks within each row, and then to one or more compute trays or fuel cell modules within each rack. The central plant area may include compressed gaseous hydrogen storage, liquid hydrogen storage, electrolysis equipment, reforming equipment, compression equipment, metering equipment, emergency isolation valves, purge equipment, and vent-handling equipment. Hydrogen may be delivered from the central plant area through one or more main supply lines to hall-level lines, then to row-level branch lines, and then to rack-level branch lines so that hydrogen is distributed in a controlled and scalable manner from plant source to compute load.

In one embodiment, the main plant-to-hall lines operate at a first pressure class selected for efficient transport across the building, while downstream hall-level, row-level, rack-level, and module-level lines operate at successively lower pressure classes selected for local safety, controllability, and fuel cell compatibility. For example, the main building lines may operate at about 50 psig to about 300 psig, hall-level lines may operate at about 20 psig to about 100 psig, row-level lines may operate at about 5 psig to about 30 psig, and rack-level supply lines may operate below about 10 psig. Pressure regulation may be staged by distance and by zone, including a first regulation stage at the hydrogen plant discharge, a second regulation stage at each hall entry, a third regulation stage at each row branch, and a fourth regulation stage at each rack inlet or module service block. Each regulation stage may be paired with shutoff valves, pressure sensors, relief devices, flow sensors, check valves, and vented isolation cavities.

In some embodiments, hydrogen is routed predominantly through overhead pathways, including ceiling-mounted utility corridors, service trays, pipe racks, or vertical drops into rows and racks, while in other embodiments hydrogen is routed through protected underfloor pathways, subfloor conduits, trenches, or side service spines. Overhead routing can be advantageous because leaked hydrogen tends to rise and can be detected and extracted at ceiling level, while underfloor routing can integrate with facilities designed for below-floor service entry. In preferred embodiments, each hall is divided into isolation zones, each row includes a row-level supply line, each rack includes a rack inlet shutoff valve and local regulator, and each tray branch includes a normally closed valve that opens only after module presence and sealing integrity are confirmed. The routing lines may be formed from hydrogen-compatible materials such as stainless steel pipe or tubing, and vent routing from relief devices, purge ports, and leak-capture cavities may be directed to a dedicated vent header or exterior discharge location so that plant-to-row piping, room-level routing, pressure control, zoning, and emergency venting are implemented in a feasible building-scale hydrogen delivery system

Although many embodiments herein are described with respect to GPUs and AI accelerators, the disclosed architecture is not limited thereto and may be used with CPUs, TPUs, NPUs, ASIC accelerators, inference processors, AI memory systems, HBM structures, switch ASICs, NICs, storage accelerators, or mixed-compute platforms. Likewise, the disclosed fuel-cell architecture is not limited to tray-level deployment and may be implemented at board level, interposer level, package level, rack level, row level, container level, or mobile data center level. The foregoing description is intended to support multiple overlapping inventive aspects, including without limitation a serviceable tray-integrated fuel-cell module, a rack-level hydrogen manifold architecture, a low-voltage high-current direct-output structure for AI loads, a hybrid transient-support arrangement for dynamic workloads, a shared thermal integration architecture, and a package-proximate or vertical power-delivery structure.

What is claimed is:

1. A power management unit for managing power delivery from a fuel cell power source to a server rack having a plurality of compute trays configured to support one or more processors, the power management unit comprising:
an electrical interface for coupling an output of a hydrogen fuel cell power module to the one or more processors, wherein the fuel cell power module is removably coupled to at least one of the plurality of compute trays;
one or more control circuits configured to control operation of the hydrogen fuel cell power module responsive to compute demand of the one or more processors; and
a direct-current to direct-current converter coupled between the fuel cell power module and a compute load corresponding to the at least one of the plurality of compute trays, the direct-current to direct-current converter being configured to impedance match an electrical output characteristic of the fuel cell power module to an electrical input characteristic of the compute load.

2. The power management unit of claim 1, wherein the hydrogen fuel cell power module is configured as a field-replaceable cartridge.

3. The power management unit of claim 1, wherein the hydrogen fuel cell power module is hot swappable while the compute tray remains installed in the server rack.

4. The power management unit of claim 1, wherein the electrical interface is configured to deliver power at a voltage between 0.6 volts and 2.5 volts.

5. The power management unit of claim 1, wherein the electrical interface is configured to deliver current greater than about 1000 amperes.

6. The power management unit of claim 1, further comprising one or more fluidic connections.

7. A power conditioning unit for managing power supplied by a fuel cell power module for powering a compute tray operating within a data center, the power condition unit comprising:
an electrical output interface configured to provide direct current power from one or more electrochemical power-generation elements to the compute tray, wherein the one or more electrochemical power-generation elements are disposed within an enclosure coupled to the compute tray; and
a direct-current to direct-current converter configured to receive direct-current output from the one or more electrochemical power-generation elements and to dynamically adjust a conversion ratio during a transient change in load demand so as to maintain an output supplied to the compute tray within a target voltage range.

8. The power conditioning unit of claim 7, wherein the enclosure is sized to occupy a 1U or 2U server-compatible envelope or a sub-envelope mounted adjacent to a compute tray.

9. The power conditioning unit of claim 7, further comprising a local controller configured to execute startup, purge, preconditioning, leak checking, fault isolation, and shutdown operations.

10. A method of managing power delivery to compute hardware, comprising:
delivering direct-current power from a fuel cell power module to one or more processors or accelerators through an electrical path, wherein the fuel cell power module is positioned at or near a compute tray;
controlling operation of the fuel cell power module responsive to demand of the one or more processors or accelerators; and
adjusting, with a direct-current to direct-current converter coupled between the fuel cell power module and a compute tray, a conversion ratio in response to a transient change in load demand so as to maintain an output supplied to the compute tray within a target voltage range.

11. The method of claim 10, further comprising compensating for a transient condition with a transient energy storage device electrically coupled to the fuel cell power module.

12. The method of claim 10, further comprising hot swapping the fuel cell power module by closing one or more fluidic fittings, isolating electrical output, releasing one or more couplings, removing the fuel cell power module, installing a replacement fuel cell power module, and restoring fluidic flow and electrical operation.

13. A power control unit for powering semiconductor processors on a plurality of circuit boards on a plurality of server racks in a data center, the power control unit comprising:
a plurality of direct-current power outputs respectively coupling a plurality of hydrogen fuel cell power modules to the plurality of circuit boards;
a direct-current to direct-current converter coupled between the fuel cell power module and a compute load and configured to adjust a conversion ratio in response to a transient load condition;
a controller configured to modulate electrical power, wherein electrical power for the plurality of semiconductor processors on the plurality of circuit boards is generated within the plurality of server racks and delivered as direct current to the plurality of semiconductor processors.

14. The power control unit of claim 13, further comprising a transient energy storage device electrically coupled to at least one of the plurality of fuel cell power modules and configured to compensate for a power spike.
